(19) United States
(12) Patent Application Publication
(10) Pub. No.: US 2014/0252555 A1
(43) Pub. Date: Sep. 11, 2014

(54) SUBSTRATE FOR FORMING ELEMENTS, AND METHOD OF MANUFACTURING THE SAME

(71) Applicant: KABUSHIKI KAISHA TOSHIBA, Tokyo (JP)

(72) Inventor: Keiji IKEDA, Tokyo (JP)

(21) Appl. No.: 14/279,912

(22) Filed: May 16, 2014

Related U.S. Application Data
(63) Continuation of application No. PCT/JP2012/079110, filed on Nov. 9, 2012.

(30) Foreign Application Priority Data
Nov. 17, 2011 (JP) 2011-251885

(51) Int. Cl. H01L 29/16; H01L 21/762

(52) U.S. Cl. CPC H01L 29/16; H01L 21/76251
USPC 257/616; 438/459

(57) ABSTRACT

According to one embodiment, a substrate for forming elements includes a substrate; an insulating film provided on the substrate; and a Ge layer or an SiGe layer bonded to the substrate via the insulating film. The insulating film is a laminated structure comprising a plurality of films including an oxide film, a high-dielectric constant insulating film, and a compound insulating film including a metal element and Ge.

### CROSS-REFERENCE TO RELATED APPLICATIONS

This application is a Continuation Application of PCT Application No. PCT/JP2012/079110, filed Nov. 9, 2012 and based upon and claiming the benefit of priority from Japanese Patent Application No. 2011-251885, filed Nov. 17, 2011, the entire contents of all of which are incorporated herein by reference.

### FIELD

Embodiments described herein relate generally to a substrate for forming elements, comprising an insulating film and a Ge or SiGe layer formed on the insulating film, and also to a method of manufacturing the substrate.

### BACKGROUND

In recent years, GOI (or SGOI) substrates have been used, each comprising an Si substrate used as support substrate, an insulating film of oxide (BOX) formed on the Si substrate, and a Ge for SiGe) layer formed on the insulating film and having a high mobility. The GOI for SGOI) substrate is greatly compatible with the conventional Si-LSIs and enables the Si-LSIs to operate faster at lower power consumption, and now attract attention as substrates that impart a new additional value to the LSIs.

Hitherto, the GOI substrate and the SGOI substrate have been made by the Ge condensation method or the bonding method. In. the Ge condensation method, however, crystal defects are introduced as the strain is relaxed. In the bonding method, crystal defects are introduced as hydrogen ions are injected to peel off the support substrate after the bonding process. The crystal defects so introduced result in residual holes, each having volume of about 10¹⁷ cm⁻³. Further, in the bonding method, an interface state has the value of 5×10¹² eV⁻¹cm⁻² or more at the Ge/BOX interface because a Ge substrate is bonded directly to the Si support substrate after an oxide film has been formed by thermal oxidation. The residual, holes and the interface state at the Ge/BOX interface prevent the normal transistor operation.

### BRIEF DESCRIPTION OF THE DRAWINGS

FIGS. 1(a) to 1(c) are sectional views showing the first half of a step of manufacturing a substrate for forming elements, according to a first embodiment;

FIGS. 2(a) to 2(c) are sectional views showing the latter half of a step of manufacturing a substrate for forming elements, according to a first embodiment;

FIGS. 3(a) to 3(c) are sectional views showing a method of manufacturing a substrate for forming elements, according to a second embodiment;

FIGS. 4(a) to 4(d) are sectional views showing a method of manufacturing a substrate for forming elements, according to a third embodiment;

FIGS. 5(a) to 5(c) are sectional views showing a method of manufacturing a substrate for forming elements, according to a fourth embodiment;

FIGS. 6(a) to 6(d) are sectional views showing a method of manufacturing a substrate for forming elements, according to a fifth embodiment; and

FIGS. 7(a) to 7(d) are sectional views showing a method of manufacturing a substrate for forming elements, according to a sixth embodiment.

### DETAILED DESCRIPTION

In general, according to one embodiment, there is provided a substrate for forming elements, comprising:
a substrate;
an insulating film provided on the substrate; and
a Ge layer or an SiGe layer bonded to the substrate via the insulating film,
wherein the insulating film is a laminated structure comprising a plurality of films including an oxide film, a high-dielectric constant insulating film, and a compound insulating film including a metal element and Ge.

This invention will be described in detail, with reference to some embodiments shown in the accompanying drawings.

### First Embodiment

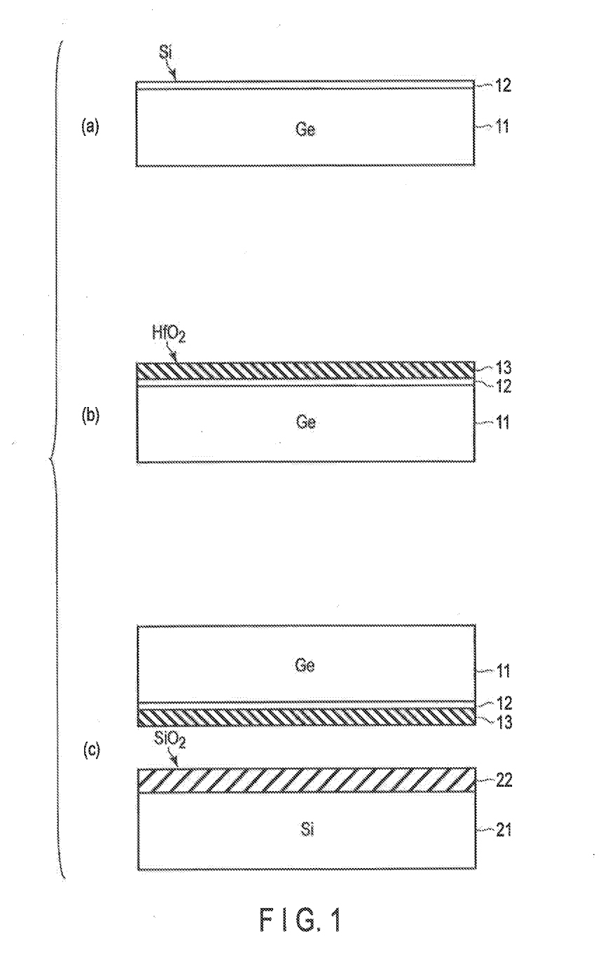

FIGS. 1(a) to 1(c) and FIGS, 2(a) to 2(c) are sectional views for explaining the method of manufacturing a substrate for forming elements, according to the first embodiment.

This embodiment is either a GUI (Ge-On-Insulator) substrate or an SGOI (SiGe-On-Insulator) substrate, with having an Si layer inserted at the interface of two layers bonded together. As an example, the GOI substrate will be described below.

First, as shown in FIG. 1(a), an Si layer 12 is formed on a Ge substrate 11, to the thickness of 0.5 nm to 1.5 nm. The Si layer 12 may be formed by, for example, ultra-high vacuum (UHV) CVD or low-pressure (LP) CVD. As feed gas, SiH₄ or Si₂H₆ may be used.

Then, as shown in FIG. 1(b), a high-k insulating film, e.g., HfO₂ film (protective film) 13, is formed on the Si layer 12, to the thickness of 4 nm. The HfO₂ film 13 may be formed by, for example, the atomic layer deposition (ALD).

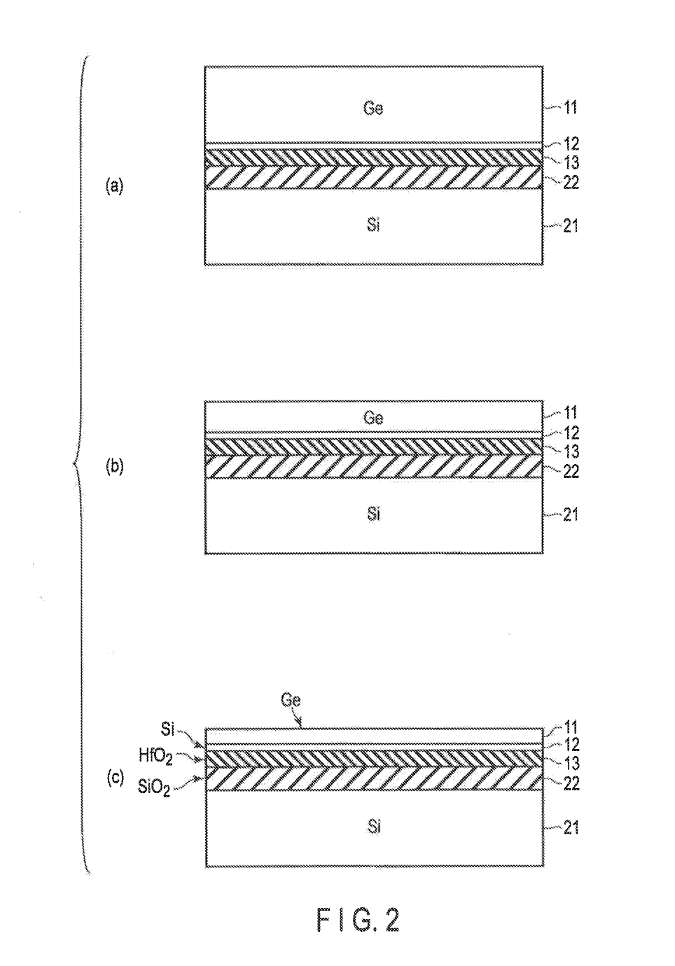

Next, as shown in FIG. 1(c), an Si substrate (support substrate) 21 is prepared, which has an Si oxide (BOX: Buried-Oxide) film 22 on one surface. To the surface of this substrate 21, the Ge substrate 10 is opposed, with the HfO₂ film 13 facing the Si oxide (BOX) film 22. Next, as shown in FIG. 2(a), after the substrates have been washed with NH₄OH, the Ge substrate 11 and the Si substrate 21 are bonded together, producing a GOI substrate. More specifically, the HfO₂ film 13 and the Si oxide film 22 are made to contact each other and are bonded to each other.

Further, as shown in FIG. 2(b), CMP method is performed, polishing the Ge substrate 11 from the back, thinning the Ge substrate 11 by about 1 μm. The Ge substrate 11 may be ground by a grinder, not to CMP. Alternatively, the Ge substrate 11 may be first ground by a grinder and then polished by CMP. Next, as shown in FIG. 2(c), the resultant structure is wet-etched with HCl: H₂O₂ mixture or NH₄OH: H₂O₂ mixture, thinning the Ge substrate 11 to 100 nm or less. The GOI substrate having the insulating film and the Ge layer formed on the insulating film is completed.

As specified above, the Ge substrate 11 is not bonded to the Si oxide film 22 formed on the Si substrate 21, but the HfO₂ film 13 is made to contact the Si oxide film 22 and bonded thereto after the Si layer 12 and HfO₂ film 13 have been formed on the surface of the Ge substrate 11. Hence, the interface state density at the interface between the Ge layer and the insulating film can be reduced to about 8×10¹¹ eV⁻¹cm⁻².

Thus, this embodiment is novel in that a layer is inserted at the Ge/BOX interface, effectively reducing the interface state density at the Ge/BOX interface. The layer so inserted can decrease the off-current of the transistor due to reduce the interface state density at the Ge/BOX interface. Moreover, the electric field generated by back-bias set to the interface state because of the reduction in the interface state density modulates the channel potential efficiently. The threshold voltage modulation achieve by the back bias can therefore be enhanced.

In this embodiment, CMP and wet etching are performed on the Ge substrate 11 after bonding the substrates together, thereby thinning the Ge substrate 11, and hydrogen ions are not injected in order to peel off the support substrate. No crystal defects are therefore introduced, and the generation of residual holes can therefore be suppressed. Moreover, the BOX layer, which is a laminated structure composed of a High-k film and a SiO₂ film by bonding the substrates, can have a small electrical thickness. As a result, any MOSFET produced by using the substrate according to this embodiment can have its threshold voltage modulated efficiently in accordance with the back bias. Thus, the MOSFET can have its threshold voltage modulated at a lower voltage than otherwise. This help to provide LSIs that can operate faster at lower power consumption.

The interface state density decreases in this embodiment, probably because the bonded interface is not the interface between the Ge layer and the insulating film since the Si layer 12 and HfO₂ film 13 are provided on the Ge substrate 11. Even if the only High-k film 13 made of HfO₂ or the like is formed on the surface of the Ge substrate 11, the interface state density will more decrease than in the case the Ge substrate 11 is directly bonded to the Si oxide film 22. In addition, the insertion of the Si layer 12 further decrease the interface state density.

In this embodiment, the material of the protective film 13 is not limited to HfO₂. Rather, it may be made of any high-dielectric constant insulating material.

### Second Embodiment

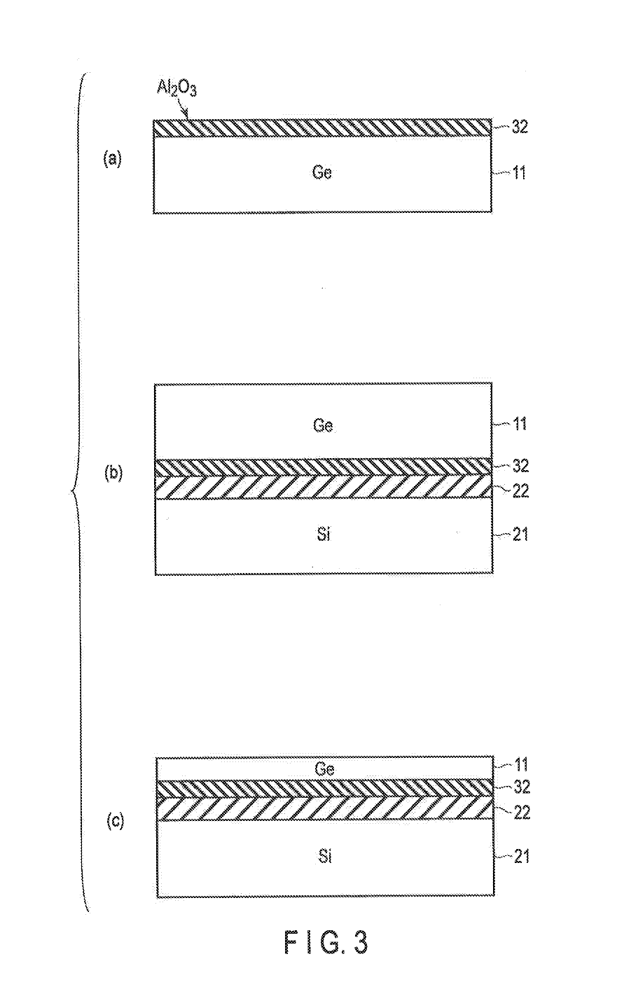

FIGS. 3(a) to 3(c) are sectional views showing a method of manufacturing a substrate for forming elements, according to the second embodiment. The components identical to those shown in FIGS. 1(a) to 1(c) and FIGS. 2(a) to 2(c) are designated by the same reference numbers and will not described in detail.

This embodiment is a GOI substrate (or SGOI substrate) having an Al₂O₃ film inserted at the interface of two layers bonded together.

First, as shown in FIG. 3(a), an Al₂O₃ film is formed on a Ge substrate 11, to thickness of about 4 nm, by means of the ALD method.

Next, as shown in FIG. 3(b), the Ge substrate 11 having the Al₂O₃ film formed on it the Ge substrate 11 is bonded to an Si substrate 21 having an Si oxide film 22 on it after the substrates have been washed with NH₄OH, producing a GOI substrate. More specifically, the Al₂O₃ film 23 formed on the Ge substrate 11 is made to contact the Si oxide film 22 formed on the Si substrate 21, thereby bonding the Ge substrate 11 to the Si substrate 21.

Then, as shown in FIG. 3(c), CMP is performed, polishing the Ge substrate 11 from the back, and wet etching is performed, thinning the Ge substrate 11. A GOI substrate having a Ge layer on the insulating film is thereby produced.

In this embodiment, an Al₂O₃ film having thickness of about 4 nm is thus formed on the surface of the substrate 11. That is, a layer capable of decreasing the interface state density is inserted at the Ge/BOX interface, successfully reducing the interface state density at the Ge/BOX interface. This embodiment can therefore achieve the same advantage the first embodiment described above. In this embodiment, the interface state density at the interface between the Ge layer and the insulating film could be decreased to about 1×10¹² eV⁻¹cm⁻².

### Third Embodiment

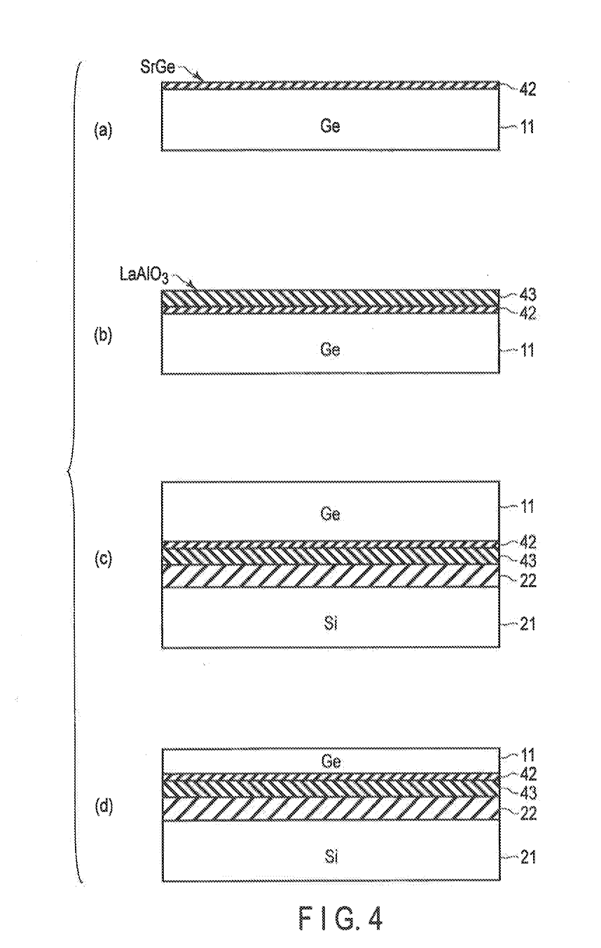

FIGS. 4(a) to 4(d) are sectional views showing a method of manufacturing a substrate for forming elements, according to the third embodiment. The components identical to those shown in FIGS. 1(a) to 1(c) and FIGS. 2(a) to 2(c) are designated by the same reference numbers and will not described in detail.

This embodiment is a GOI (or SGOI) substrate in which a SrGe film is inserted at the interface of two layers bonded together.

First, as shown in FIG. 4(a), Sr is deposited on a Ge substrate 11 by the molecular beam epitaxy (MBE) method or the ALD method. Then, the resultant structure is annealed, forming an SrGeₓ film (compound insulating film) 42 having thickness of about 1 nm.

Then, as shown in FIG. 4(b), an LaAlO₃ film 43, which will be used as protective film, is formed on the SrGeₓ film 42 by the MBE method or the ALD method. The LaAlO₃ film 43 is provided to prevent the SrGeₓ film 42 from contacting the atmosphere and from being degraded.

Next, as shown in FIG. 4(c), the Ge substrate 11 and Si substrate 21 are bonded together, with the LaAlO₃ film 43 and Si oxide film 22 contacting each other. A GOI substrate is thereby produced.

Further, as shown in FIG. 4(d), CMP is performed, polishing the Ge substrate 11 from the back, and wet etching is then performed, thinning the Ge substrate 11 to about 100 nm or less. A GOI substrate having a Ge layer on the insulating film is thereby produced.

In this embodiment, an LaAlO₃ film 43 is formed on the surface of the Ge substrate 11, to the thickness of about 1 nm, thereby inserting, at the Ge/BOX interface, a layer that can decrease the interface state density at the Ge/BOX interface. Thus, the interface state density is decreased at the Ge/BOX interface. As a result, this embodiment can achieve the same advantage as the first embodiment. In this embodiment, the interface state density at the interface between the Ge layer and the insulating film was decreased to 7×10¹¹ eV⁻¹cm⁻² or less.

In this embodiment, the material of the compound insulating film formed on the Ge substrate 11 is not limited to SrGe. Rather, any compound composed of Ge and metal and dielectric materials can be used. The compound insulating film may be made of BaGe, for example. Moreover, the protective film 43 formed on the compound insulating film is not limited to a LaAlO₃ film. It may be any high-dielectric constant insulating film.

### Fourth Embodiment

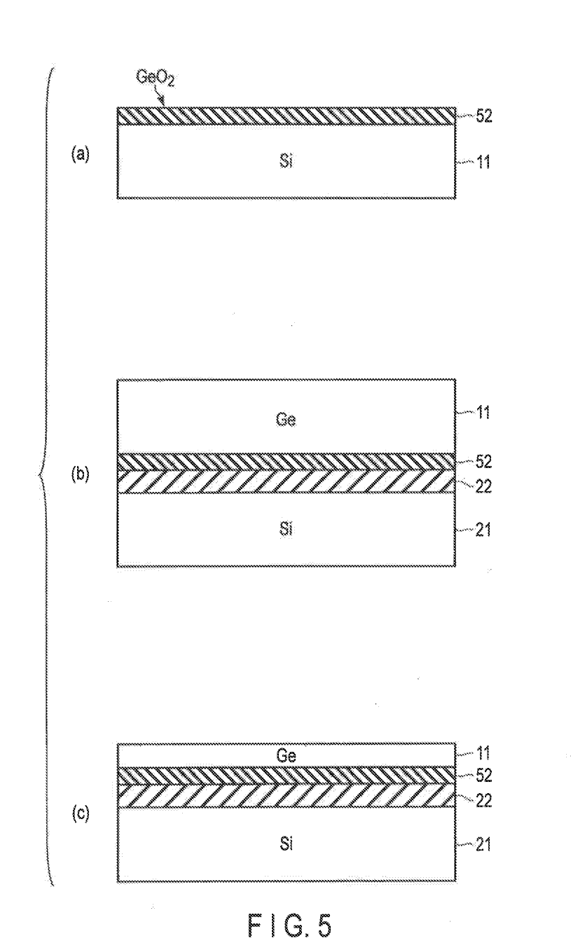

FIGS. 5(a) to 5(c) are sectional views showing a method of manufacturing a substrate for forming elements, according to the fourth embodiment. The components identical to those shown in FIGS. 1(a) to 1(c) and FIGS. 2(a) to 2(c) are designated by the same reference numbers and will not described in detail.

This embodiment is a GOI (or SGOI) substrate in which a GeO₂ film is inserted at the interface of two layers bonded together.

First, as shown in FIG. 5(a), plasma oxidation is performed, forming a GeO₂ film on the surface of a Ge substrate 11.

Then, as shown in FIG. 5(b), the Ge substrate 11 having the GeO₂ film on its surface is bonded to an Si substrate 21 having a thermally oxidized film 22 on its surface, thus forming a GOI substrate. More specifically, a GeO₂ film 52 and an Si oxide film 22 are set in mutual contact and are then bonded together. The GeO₂/Ge interface by forming the plasma oxidation is better than a natural oxide film formed by wet etching. Further, the interface state density Dit at the GeO₂/Ge interface can be decreased to Dit=2×10¹¹ eV⁻¹cm⁻².

Next, as shown in FIG. 5(c), CMP is performed, polishing the Ge substrate 11 from the back, and wet etching is then performed. A GOI substrate having a Ge layer on the insulating film is thereby produced.

In this embodiment, a GeO₂ film 52 is formed on the surface of the Ge substrate 11, inserting a layer capable of decreasing the interface state density. The interface state density is therefore decreased at the Ge/BOX interface. Hence, this embodiment achieves the same advantage as the first embodiment.

### Fifth Embodiment

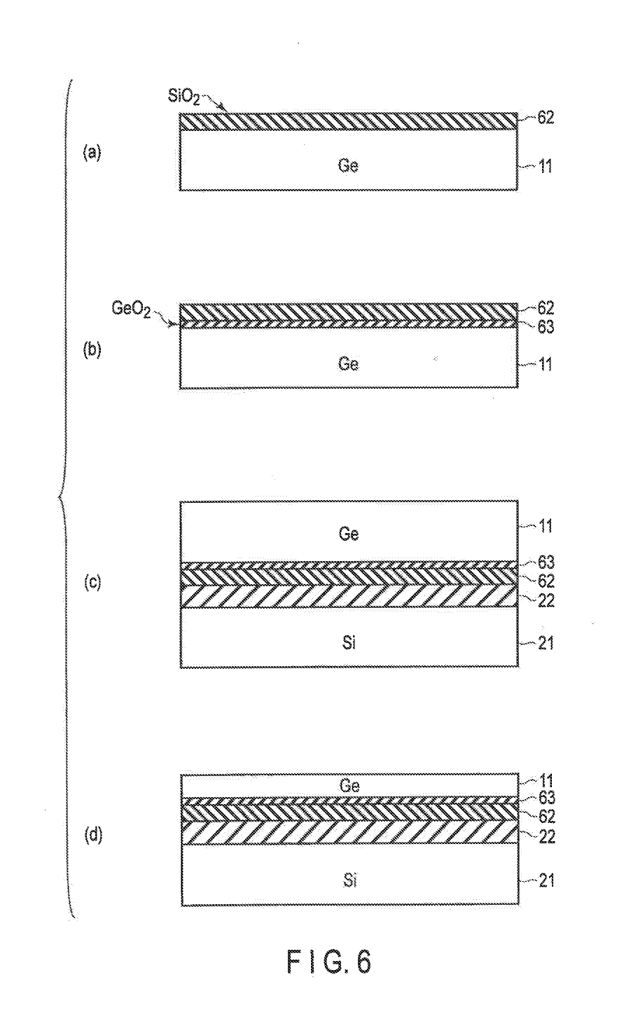

FIGS. 6(a) to 6(d) are sectional views showing a method of manufacturing a substrate for forming elements, according to the fifth embodiment. The components identical to those shown in FIGS. 1(a) to 1(c) and FIGS. 2(a) to 2(c) are designated by the same reference numbers and will not described in detail.

This embodiment is a GOI (or SGOI) substrate in which a SiO₂/GeO₂ film structure is inserted at the interface of two layers bonded together.

First, LPCVD method is performed, forming an SiO₂ film 62 having thickness of about 3 nm on the surface of a Ge substrate 11 as shown in FIG. 6(a). Then, the substrate is subjected to through oxidation by means of plasma oxidation or thermal oxidation. As a result, a GeO₂ film 63 is formed between the Ge substrate 11 and the SiO₂ film 62 shown in FIG. 6(b).

The GeO₂ film 63 is unstable in the atmosphere, and should not be exposed directly to the atmosphere. In this embodiment, the through oxidation is performed after the SiO₂ film 62 has been formed, thus preventing the GeO₂ film 63 from being exposed directly to the atmosphere.

The SiO₂/Ge interface, which has been formed on the surface of the Ge substrate 11 by plasma oxidation, is better than a natural oxide film formed by wet etching. Its interface state interface state density can be decreased to Dit=5×10¹⁰ eV⁻¹cm⁻².

Next, as shown in FIG. 6(c), the Ge substrate 11, on which the SiO₂ film 62 and GeO₂ film 63 are formed, is bonded to an Si substrate 21 having a thermal oxide film 22 such as an Si oxide film, thereby forming a GOI substrate. More specifically, the GeO₂ film 63 and the Si oxide film 22 are set in mutual contact and then bonded to each other.

Then, as shown in FIG. 6(d), CMP is performed, polishing the Ge substrate 11 from the back, and wet etching is performed. A GOI substrate having a Ge layer on the insulating film is thereby produced.

In this embodiment, the SiO₂ film 62 and GeO₂ film 63 are formed on the surface of the Ge substrate 11. Thus, a layer, which can decrease the interface state density, can be inserted at the Ge/BOX interface. The interface state density at the Ge/BOX interface is therefore decreased. This embodiment thus achieves the same advantage as the first embodiment described above.

### Sixth Embodiment

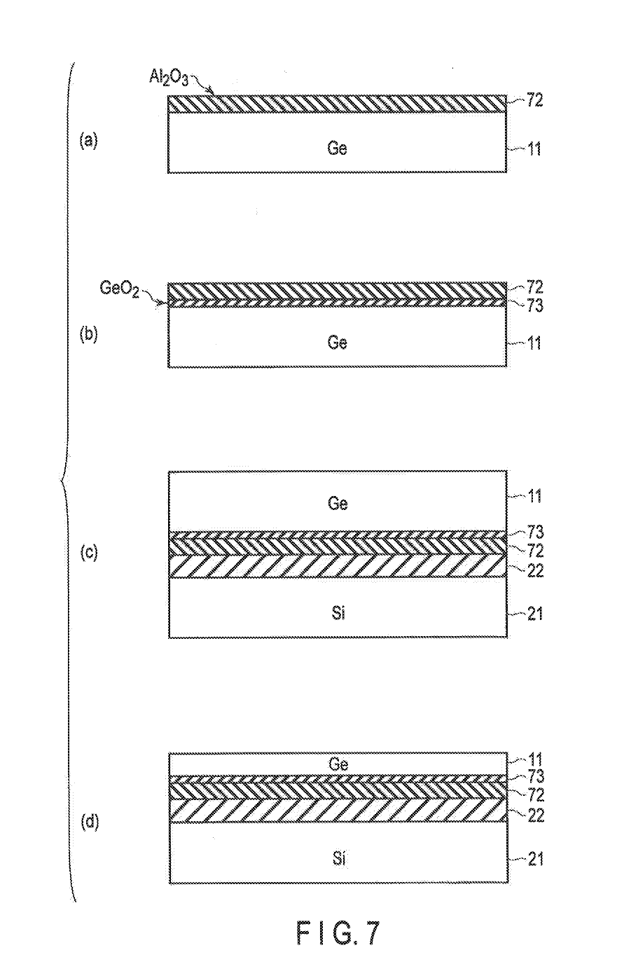

FIGS. 7(a) to 7(d) are sectional views showing a method of manufacturing a substrate for forming elements, according to the sixth embodiment. The components identical to those shown in FIGS. 1(a) to 1(c) and FIGS. 2(a) to 2(c) are designated by the same reference numbers and will not described in detail.

This embodiment is a GOI (or SGOI) substrate in which an Al₂O₂/GeO₂ film structure is inserted at the interface of two layers bonded together.

First, as shown in FIG. 7(a), the ALD method is performed, forming an Al₂O₃ film 72 having thickness of about 1 nm, on the surface of a Ge substrate 11. Then, the substrate is subjected to through oxidation by means of plasma oxidation or thermal oxidation. As a result, a GeO₂ film 73 is formed between the Ge substrate 11 and the Al₂O₃ film 72, as shown in FIG. 7(b).

Next, as shown in FIG. 7(c), the Ge substrate 11 having the Al₂O₃ film 72 and GeO₂ film 7 is bonded to the Si substrate 21 having a Si oxide film 22, thereby forming a GOI substrate. More specifically, the Al₂O₃ film 72 and the Si oxide film 22 are set in mutual contact and then bonded to each other.

The Al₂O₃/GeO₂/Ge interface, which is formed on the Ge substrate 11 by plasma oxidation, is better than a natural oxide film formed by wet etching, and can decrease the interface state density to Dit=5×10¹⁰ eV⁻¹cm⁻².

Next, as shown in FIG. 7(d), CMP is performed, polishing the Ge substrate 11 from the back, and wet etching is then performed. As a result, a GOI substrate having a Ge layer on the insulating film is produced.

In this embodiment, an Al₂O₃ film and a GeO₂ film are formed on the surface of the Ge substrate 11, inserting a layer capable of decreasing the interface state density at the Ge/BOX interface. Thus, the interface state density can he decreased at the Ge/BOX bonding interface. This embodiment therefore achieves the same advantage as the first embodiment.

(Modification)

This invention is not limited to the embodiments described above.

The embodiments described above have a Ge substrate. A substrate composed of a Ge substrate and an SiGe layer formed on the Ge substrate may be used, instead, to produce an SGOI substrate. In this case, compressive strain is induced to the SiGe layer formed on the Ge substrate. The strain remains in the SiGe layer even after the Ge substrate is removed, and is useful in fabricating a transistor utilizing a strained-SiGe channel. The use of the substrate for forming elements, according to the embodiments, is not limited to the manufacture of devices such as transistors. The substrate can be used as substrate for fabricating solar batteries, waveguides, etc.

While certain embodiments have been described, these embodiments have been presented by way of example only, and are not intended to limit the scope of the inventions. Indeed, the novel embodiments described herein may he embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate for forming elements, comprising:
a substrate;
an insulating film provided on the substrate; and
a Ge layer or an SiGe layer bonded to the substrate via the insulating film,
wherein the insulating film is a laminated structure comprising a plurality of films including an oxide film, a high-dielectric constant insulating film, and a compound insulating film including a metal element and Ge.

2. The substrate according to claim 1, wherein the oxide film is an Si oxide film.

3. The substrate according to claim 1, wherein the substrate is an Si substrate.

4. A substrate for forming elements, comprising:
a substrate;
an insulating film provided on the substrate; and
a Ge layer or an SiGe layer bonded to the substrate via the insulating film,
wherein the insulating film is a laminated structure comprising a plurality of films including an oxide film, a high-dielectric constant insulating film, and a Ge oxide film.

5. The substrate according to claim 4, wherein the oxide film is an Si oxide film.

6. The substrate according to claim 4, wherein the substrate is an Si substrate.

7. A method of manufacturing a substrate for forming elements, the method comprising:
forming a compound insulating film including a metal element and Ge, on a Ge substrate;
forming a high-dielectric constant insulating film on the compound insulating film;
bonding the Ge substrate having the compound insulating film and the high-dielectric constant insulating film to the support substrate having an oxide film on a surface, with the high-dielectric constant insulating film and the oxide film contacting each other; and
polishing the Ge substrate bonded to the support substrate, from the back, thereby making the Ge substrate thinner.

8. The method according to claim 7, wherein the oxide film is an Si oxide film.

9. The method according to claim 7, wherein the support substrate is an Si substrate.

10. A method of manufacturing a substrate for forming elements, the method comprising:
forming a high-dielectric constant insulating film on a Ge substrate;
forming a Ge oxide film between the Ge substrate and the high-dielectric constant insulating film by plasma oxidation or thermal oxidation;
bonding the Ge substrate having the high-dielectric constant insulating film and the Ge oxide film to a support substrate having an oxide film, with the high-dielectric constant insulating film and the oxide film contacting each other; and
polishing the Ge substrate bonded to the support substrate, from the back, thereby making the Ge substrate thinner.

11. The method according to claim 10, wherein the oxide film is an Si oxide film.

12. The method according to claim 10, wherein the support substrate is an Si substrate.
